(19) United States
(12) Patent Application Publication
(10) Pub. No.: US 2010/0279010 A1
(43) Pub. Date: Nov. 4, 2010

(54) METHOD AND SYSTEM FOR CLOSE PROXIMITY CATALYSIS FOR CARBON NANOTUBE SYNTHESIS

(75) Inventors: Harry C. Malecki, Abingdon, MD (US); Tushar K. Shah, Columbia, MD (US)

Correspondence Address: MCDERMOTT WILL & EMERY LLP, 18191 VON KARMAN AVE., SUITE 500, IRVINE, CA, 92612-7108, US

(73) Assignee: Lockheed Martin Corporation, Bethesda, MD (US)

(21) Appl. No.: 12/767,721

(22) Filed: Apr. 26, 2010

Related U.S. Application Data
(60) Provisional application No. 61/174,335, filed on Apr. 30, 2009.

(51) Int. Cl. C23C 16/44; C23C 16/26

(52) U.S. Cl. 427/249.1; 118/724; 977/742; 977/843

(57) ABSTRACT

A method for carbon nanotube synthesis can include providing in a growth chamber, a substrate in close proximity with a surface of a first plate having a catalyst. The method can also include heating the growth chamber to a temperature sufficient to cause transfer of catalytic particles from the first plate to the substrate. The method can also include growing carbon nanotubes on the substrate by directing feed gas to the substrate.

### STATEMENT OF RELATED APPLICATIONS

This application claims priority to U.S. Provisional Application No. 61/174,335 filed Apr. 30, 2009, which is hereby incorporated by reference in its entirety.

### STATEMENT REGARDING FEDERALLY SPONSORED RESEARCH OR DEVELOPMENT

Not applicable.

### FIELD OF THE INVENTION

The present invention relates in general to a system, method, and apparatus for synthesis of carbon nanotubes.

### BACKGROUND OF THE INVENTION

Carbon nanotube (“CNT”) synthesis typically requires an elevated temperature, a catalyst, and a carbon source (e.g., feed gas). Generally, a catalyst is applied to the surface of substrate (e.g., a fiber) to initiate the growth of CNTs thereon in a growth chamber. In order to apply the catalyst to the substrate surface, the substrate is typically dipped or soaked in a colloidal or liquid solution containing catalyst compounds. However, in the case of colloidal particle liquid solutions, the dipping process can lead to uneven or poor overall coating. For many liquid solutions, extended dip and soaking times are required to effectively apply the catalyst compounds to the surface of the substrate. Moreover, additional steps may be required to convert the catalyst compounds to usable catalyst particles.

### SUMMARY OF THE INVENTION

In some aspects, embodiments disclosed herein relate to methods and systems for carbon nanotube synthesis. A method for carbon nanotube synthesis can comprise providing in a growth chamber, a substrate in close proximity with a surface of a first plate comprising a catalyst; heating the growth chamber to a temperature sufficient to cause transfer of catalytic particles from the first plate to the substrate; and growing carbon nanotubes on the substrate by directing feed gas to the substrate. A system for carbon nanotube synthesis can comprise a growth chamber; a heater configured to heat the growth chamber; a first plate comprising a catalyst, wherein the first plate is configured to fit within the growth chamber, and wherein a surface of the first plate faces a substrate; and a substrate configured to fit in close proximity with the surface of the first plate.

### BRIEF DESCRIPTION OF THE DRAWINGS

FIG. 1 shows a schematic diagram of a growth assembly for facilitating CNT growth on a substrate, according to an embodiment of the invention.

FIG. 2 shows a schematic diagram of a growth assembly for facilitating CNT growth on a substrate, according to another embodiment of the invention.

FIG. 3 shows a schematic diagram of a CNT growth system using the growth assembly of FIG. 1, according to an embodiment of the invention.

FIG. 4 shows a schematic diagram of a CNT growth system using the growth assembly of FIG. 2, according to another embodiment of the invention.

FIG. 5 shows a process flow for CNT growth according to an embodiment of the invention.

FIG. 6 shows CNT growth on an E-Glass fabric substrate using a copper plate-based close proximity catalysis process.

### DETAILED DESCRIPTION

The present invention relates in general to a system, method, and apparatus for synthesis of carbon nanotubes. In accordance with some embodiments, a catalyst is applied to a substrate surface during the growth process, allowing for CNT growth on substrates without previously applying a catalyst coating thereto, unlike current processes wherein a catalyst coating is separately applied to a substrate prior to the introduction of the substrate into a growth chamber for CNT synthesis. In these embodiments, the process involves the formation of a growth sample assembly including a substrate sandwiched between two roughened metal plates formed of a catalytic transition metal. The substrate is maintained in close proximity to the plates (e.g., in intimate contact or surface engagement) to facilitate transfer of catalyst particles from the plates to the substrate. The growth sample assembly is introduced into an inert environment and heat is applied, increasing the temperature therein to a level sufficient to cause transfer of catalyst particles from the plates to the substrate. This temperature level can range from about 500 to about 1000° C. A carbon source (e.g., feed gas) is introduced in the environment (e.g., vapor deposition at rates ranging from about 0 to about 25% of the total gas flow) and applied to the substrate at a target temperature sufficient to synthesize CNTs on the substrate. These conditions can be controlled for a residence time (e.g., ranging from about 30 seconds to several minutes) according to the target length of the CNTs grown. Upon completion of the catalysis and CNT synthesis process, the growth sample assembly is cooled to a second temperature (e.g., lower than about 400° C.) in an inert atmosphere prior to removal from the inert environment. The cooling process can help ensure that the deposited carbon material will not burn off (i.e., become undesirably oxidized in the external environment). The resulting product is a substrate with nanotubes grown on the substrate surface. In this manner, the catalyst application step and CNT growth step can be combined into a single process step.

As used herein, the term “carbon nanotube” (CNT, plural CNTs) refers to any of a number of cylindrically-shaped allotropes of carbon of the fullerene family including single-walled carbon nanotubes (SWNTs), double-walled carbon nanotubes (DWNTs), multi-walled carbon nanotubes (MWNTs). CNTs can be capped by a fullerene-like structure or open-ended. CNTs include those that encapsulate other materials. Carbon nanotubes exhibit impressive physical properties. The strongest CNTs exhibit roughly eighty times the strength, six times the toughness (i.e., Young's Modulus), and one-sixth the density of high carbon steel.

As used herein, the term “transition metal” refers to any element or alloy of elements in the d-block of the periodic table. The term “transition metal” also includes salt forms of the base transition metal element such as oxides, carbides, nitrides, and the like.

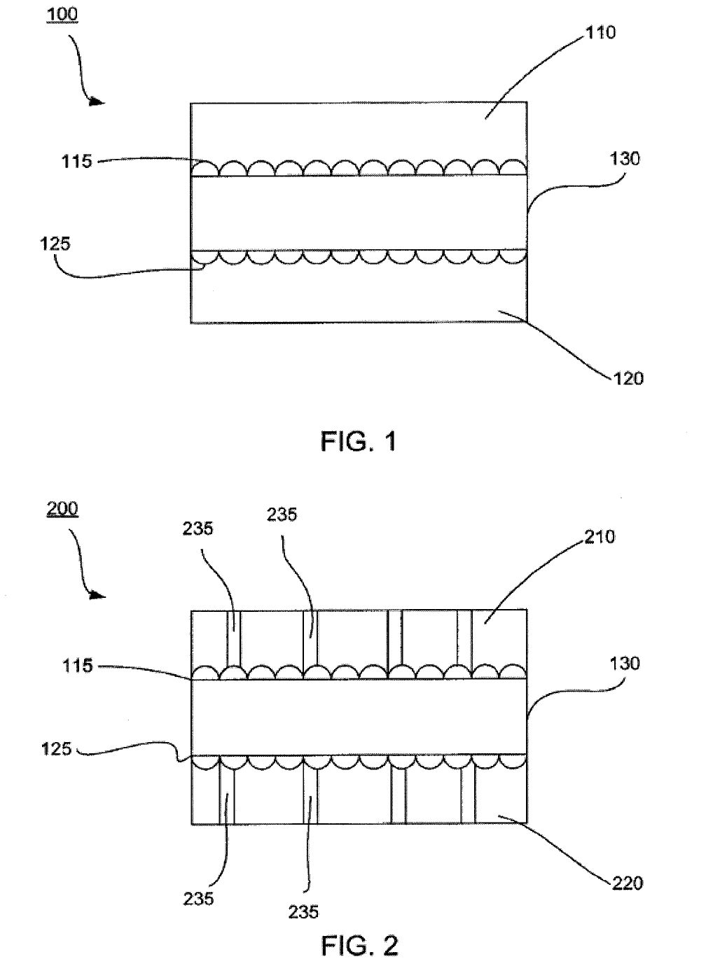

Referring to FIG. 1, in accordance with an embodiment of the present invention, growth assembly 100 can include includes first plate 110 and second plate 120 and substrate 130 upon which CNTs can be synthesized. In some embodiments, growth assembly 100 can be configured with just a single plate. In some such embodiments, substrate 130 can be a substantially 2-dimensional surface upon which CNT growth on one side is to be effected. Surface 115 of first plate 110 and/or surface 125 of second plate 120 can be untreated, but are preferably roughened to a predetermined level to facilitate material transfer. Sanding or grinding wheels such as aluminum oxide sanding wheels can be used to roughen surfaces 115, 125. In an exemplary embodiment, surfaces 115, 125 can be roughened to have a roughness height rating ranging from about 2 to 1000 micro inches. These and other roughening processes and equipments are known in the art, and are thus not described in further detail for sake of brevity.

Substrate 130 can be configured to fit between first and second plates 110, 120, either partially or completely. Substrate 130 can be placed or otherwise disposed (e.g., “sandwiched”) between roughened surfaces 115, 125 such that surfaces of substrate 130 are in intimate contact or surface engagement with roughened surfaces 115, 125. This and the remaining illustrative embodiments can be used with any type of substrate. The term “substrate” is intended to include any material upon which CNTs can be synthesized and can include, but is not limited to, a carbon fiber, a graphite fiber, a cellulosic fiber, a glass fiber, a metal fiber (e.g., steel, aluminum, etc.), a metallic fiber, a ceramic fiber, a metallic-ceramic fiber, an aramid fiber, or any substrate comprising a combination thereof. The substrate can include fibers or filaments arranged, for example, in a fiber tow (typically having about 1000 to about 12000 fibers) as well as planar substrates such as fabrics, tapes, or other fiber broadgoods, and materials upon which CNTs can be synthesized. In one preferred embodiment, substrate 130 is a glass fiber.

As illustrated in FIG. 1, the surfaces of substrate 130 can be generally planar and configured in intimate contact with roughened surfaces 115, 125. However, other embodiments can include substrate 130 having a contoured profile. In this case, roughened surfaces 115, 125 can also be contoured in complimentary fashion to provide surface engagement with substrate 130.

In an exemplary embodiment, first and second plates 110, 120 have a length of about 7 inches and a width of about 5 inches. In another embodiment, first and second plates 110, 120 have a length of about 36 inches and a width of about 36 inches. The dimensions of plates 110, 120 can be adjusted according to the dimensions of substrate 130, depending on the requirements for a given application. Thus, there are no limitations on the dimensions of the two plates and the dimensions can be guided by the substrate dimensions. In other embodiments, the dimensions can be fixed independent of the substrate dimensions and the substrate can be dynamically moved through the plates in a continuous in-line process. In some embodiments, the width of such a system can be over 60 inches wide and 240 inches long, although the length of the system can be adjusted depending on the desired rate of motion of the substrate through the process.

First and/or second plates 110, 120 include a catalyst. In an exemplary embodiment, first and/or second plates 110, 120 can be copper plates (i.e., the catalyst is copper). In other embodiments, first and/or second plates 110, 120 can be fabricated from other catalysts, such as transition metals (e.g., iron, nickel, cobalt, molybdenum or an alloy thereof). First and/or second plates 110, 120 can be made of any material which can be used for the preparation carbon nanotubes, including, without limitation, any d-block transition metal, salts thereof, and mixtures thereof. In some embodiments, first and/or second plates 110, 120 can have different compositions. For example, in some embodiments, first plate 110 can be made of copper, while second plate 120 can be made of cobalt.

Referring to FIG. 2, in accordance with another embodiment of the present invention, growth assembly 200 can be generally similar to growth assembly 100. Either or both of first plate 210 and second plate 220 can have one or more openings 235 (e.g., through apertures or gas ports). Feed gas can be directed onto substrate 130 through openings 235 or via a gas manifold or diffuser having one or more gas nozzles or injectors. First and second plates 210, 220 can otherwise have similar composition and construction as first and second plates 110, 120 of FIG. 1.

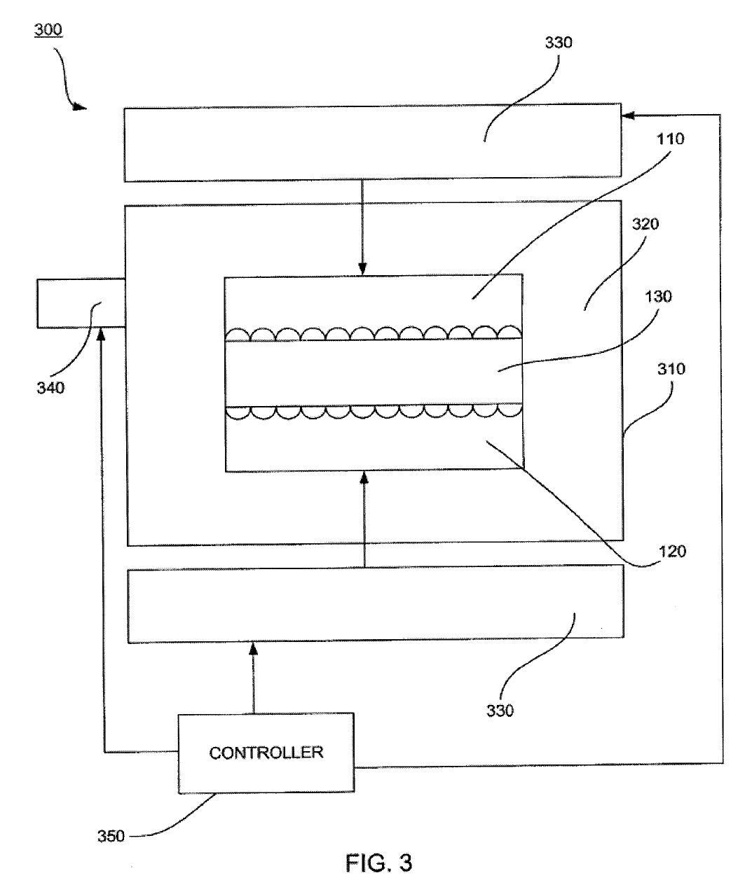

Referring to FIG. 3, in accordance with an embodiment of the present invention, CNT growth system 300 can include growth chamber 310. Growth chamber 310 can generally be an enclosure within which first and second plates 110, 120 are configured to fit. CNT growth system 300 can include one or more heaters 330, and controller 350. In an exemplary embodiment, CNT growth system 300 can further include grinding or sanding wheels (not shown) for roughening first and second plates 110, 120. In an exemplary embodiment, growth chamber 310 is a closed, batch-operation reactor, while in other embodiments the growth chamber is open allowing for continuous processing.

Heaters 330 can be thermally coupled to first and second plates 110, 120. Heaters 330 can be resistive heaters, induction heaters, or any other device configured to heat growth chamber 310.

Controller 350 can be adapted to independently sense, monitor, and control system parameters including one or more of feed gas rate, inert gas rate, temperature within growth chamber 310, and heaters 330. Controller 350 can be an integrated, automated computerized system controller that receives parameter data and performs various automated adjustments of control parameters or a manual control arrangement, as is understood by one of ordinary skill in the art.

In various embodiments, CNT growth system 300 can operate at atmospheric pressure, or at pressures lower than atmospheric pressure. In some embodiments, first and second plates 110, 120 can be roughened before substrate 130 is disposed therebetween. With substrate 130 in place, CNT growth system 300 can be sealed to the external environment.

Growth chamber 310 can be adapted to contain an inert environment therewithin. In an exemplary embodiment, inert gas 320 can be introduced into growth chamber 310 via inlet 340 to create the inert environment. Inert gas 320 can include, but is not limited to argon, helium, or nitrogen. Controller 350 can control the flow of inert gas 320 into and out of growth chamber 310. An inert gas source (not shown) can be in fluid communication with growth chamber 310 via inlet 340.

Feed gas can be fed into growth chamber 310 via inlet 340, as controlled by controller 350. Inlet 340 can be attached to one or both of first and second plates 110, 120 and feed gas can be fed through first and/or second plates 110, 120 to provide a more even distribution over the area of substrate 130. In another embodiment, growth chamber 310 can have separate inlets (not shown) for inert gas and feed gas. As used herein, the term “feed gas” refers to any carbon compound gas, solid, or liquid that can be volatilized, nebulized, atomized, or otherwise fluidized and is capable of dissociating or cracking at high temperatures (e.g. about 350° C. to about 900° C.) into at least some free carbon radicals and which, in the presence of a catalyst, can form CNTs on the substrate. In some embodiments, feed gas can comprise acetylene, ethane, ethylene, methanol, methane, propane, benzene, natural gas, other hydrocarbon gas, or any combination thereof.

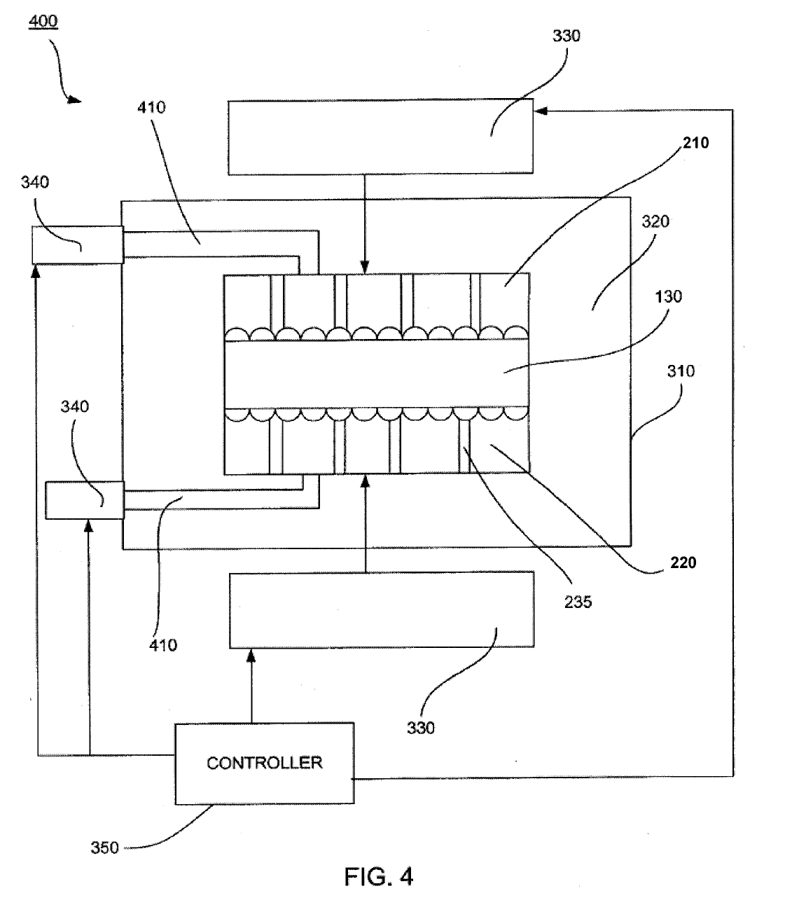

Referring now to FIG. 4, in another embodiment, CNT growth system 400 can include Growth chamber 310 and growth assembly 200 (see FIG. 2), and can allow feed gas to be supplied to substrate 130 via openings 235 in first and/or second plates 210, 220. Ducts 410 can direct feed gas from inlet 340 to first and second plates 210, 220. Openings 235 can be arranged in size and shape to provide substantially uniform dispersion of feed gas to substrate 130. The distribution of synthesized CNTs on substrate 130 can be tailored by appropriate distribution of openings 235 in first and second plates 210, 220. In some embodiments, openings 235 can exist within a range of 1/16 inch to as great as ¼ inch in diameter, with a spacing of dimension equivalent to 20 times greater than the hole diameter, where the holes are placed in a evenly spaced array. In other embodiments, opening 235 can consist of a slot which spans the entire length of first and second plates 210, 220. In this case, the slot can have a width of 1/16 inch to ¼ inch and a spacing of dimension equivalent to 20 times greater than the slot width dimension, where the slots are separated in linear arrangement.

Because oxygen can be detrimental to CNT growth, inert gas 320 can displace oxygen from growth chamber 310. When oxygen is present in growth chamber 310, the free carbon radicals formed from feed gas tend to react with the oxygen to form carbon dioxide and carbon monoxide, instead of forming CNTs on substrate 130. Oxygen can also unfavorably react with preformed CNTs and degrade their structure. Oxygen within growth chamber 310 may also undesirably oxidize substrate 130 and first and second plates 110, 120 at elevated temperatures. In an exemplary embodiment, feed gas is acetylene and inert gas is nitrogen. In other embodiments, feed gas can be methane or ethylene. In one embodiment, feed gas can be about 25% of the total volumetric flow rate of gases supplied to growth chamber 310. In another embodiment, feed gas can be as low as 0.5% of the total volumetric flow rate of gases supplied to growth chamber 310.

The use of a carbon feedstock such as acetylene can reduce the need for a separate process of introducing hydrogen into growth chamber 310, which can be used to reduce a catalyst containing an oxide. The dissociation of a carbon feedstock may provide hydrogen, which can reduce the catalyst particles to pure particles or at least to an acceptable oxide level. Without being bound by theory, it is believed that the stability of an oxide used as a catalyst can affect the reactivity of the catalyst particles. As the stability of the oxide increases, the catalyst particles generally become less reactive. Reduction (e.g., through contact with hydrogen) to a more unstable oxide or a pure metal can increase the reactivity of the catalyst. For example, if the catalyst comprises iron oxide, such an iron oxide particle is not conducive to the synthesis of CNTs due to the stability of the iron oxide. Reduction to a less stable oxidation state or pure iron can increase the reactivity of the catalyst particle. The hydrogen from acetylene can remove the oxide from the catalyst particles or reduce the oxide to a less stable oxide form.

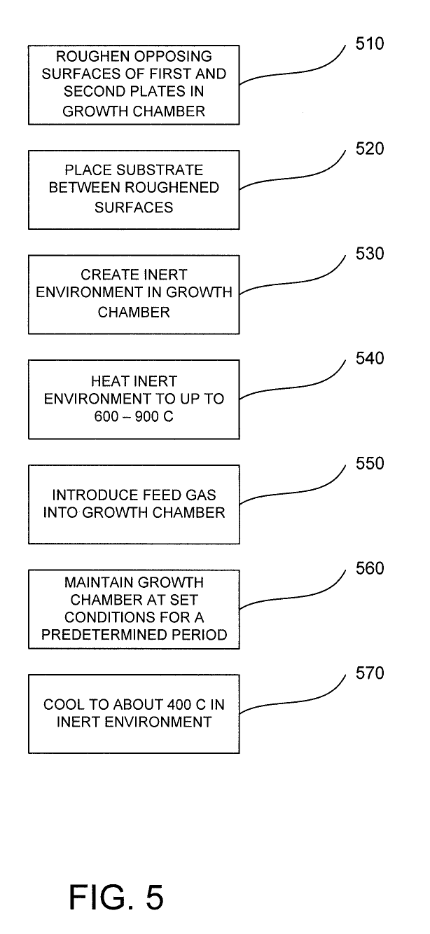

Now referring to FIG. 5, there is illustrated a process flow for a method for growing CNTs on substrate 130 using a close proximity catalysis process, according to an embodiment of the present invention. At block 510, at least two opposing surfaces (e.g., 115, 125) of first and second plates (e.g., 110, 120) in growth chamber 310 are roughened. At block 520, substrate 130 is disposed between roughened surfaces (e.g., 115, 125) of first and second plates (e.g., 110, 120). Substrate 130 can be in intimate contact or surface engagement with roughened surfaces of first and second plates. At block 530, an inert environment can be created within growth chamber 310 by introducing inert gas. At block 540, the inert environment within growth chamber 310 is heated to a temperature level sufficient for transfer of catalyst particles from first and second plates (e.g., 110, 120) to substrate 130. The temperature level can range from about 500° C. to about 900° C. In one embodiment, once the desired temperature level within growth chamber 310 is reached, the temperature can be maintained for a “dwelling period” ranging from several seconds to about several minutes to facilitate the transfer of catalyst particles from first and second plates (e.g., 110, 120) to substrate 130. At the end of the dwelling period, a feed gas can be introduced into growth chamber 310, per block 550, and directed onto substrate 130. Thus, in this embodiment, catalyst particles can be applied to substrate 130 followed by synthesis of CNTs thereon.

In another embodiment, as soon as the desired temperature level is reached in growth chamber 310, feed gas can be introduced into growth chamber 310 and directed at substrate 130. In this embodiment, the catalyst particles can be applied to substrate 130 and CNTs can be synthesized thereon contemporaneously. At block 560, the operating conditions of growth chamber 310, such as the temperature and the proportion of feed gas therewithin, can be maintained for a predetermined period of time. The time can range from about 30 seconds to about several minutes, thereby controlling the length of CNTs grown on substrate 130. Increased length of CNTs may generally be obtained by increasing the time substrate 130 is subjected to growth chamber conditions. At block 570, first and second plates (e.g., 110, 120) along with substrate 130 can be cooled to a lower temperature (e.g., below about 400° C.) in the inert environment. The cooling can be achieved, for example, by using water or other liquid cooling systems (not shown) in thermal coupling with first plate (e.g. 110), second plate (e.g., 120), and/or substrate 130. Cooling may ensure that synthesized CNTs on substrate 130, substrate 130, and first and second plates 110, 120 are not undesirably oxidized by oxygen present in the external environment. The resulting product is substrate 130 with CNTs grown thereon. It is believed that CNTs are synthesized on substrate 130 on locations where feature tips of roughened surfaces 115, 125 either are in contact with substrate 130 or are sufficiently close to substrate 130 to facilitate synthesis of CNTs thereon. Accordingly, it is further believed that the higher the number of feature tips of roughened surfaces 115, 125 in contact with substrate 130, the higher the number of CNTs synthesized on substrate 130.

A potential advantage of the system and the method of this invention is that, unlike known systems and methods of CNT synthesis, the substrates need not undergo a separate catalyst application step. The catalyst application on the surface of the substrate is combined with the CNT synthesis process and is performed within the growth chamber. Although some ferrocene based processes do not require a separate catalyst application step, there exist risk and safety concerns associated with airborne CNTs in such processes. Such risks and concerns may be mitigated using the processes described herein.

In some embodiments, the apparatus of the present invention results in the production of carbon-nanotube infused substrates. As used herein, the term “infused” means chemically or physically bonded and “infusion” means the process of bonding. Such bonding can involve direct covalent bonding, ionic bonding, pi-pi, and/or van der Waals force-mediated physisorption. For example, in some embodiments, the CNTs can be directly bonded to the substrate. Additionally, it is believed that some degree of mechanical interlocking occurs as well. Bonding can be indirect, such as the CNT infusion to the substrate via a barrier coating and/or an intervening transition metal nanoparticle disposed between the CNTs and substrate. In the CNT-infused substrates disclosed herein, the carbon nanotubes can be “infused” to the substrate directly or indirectly as described above. The particular manner in which a CNT is “infused” to a substrate is referred to as a “bonding motif.”

CNTs useful for infusion to substrates include single-walled CNTs, double-walled CNTs, multi-walled CNTs, and mixtures thereof. The exact CNTs to be used depends on the application of the CNT-infused substrate. CNTs can be used for thermal and/or electrical conductivity applications, or as insulators. In some embodiments, the infused carbon nanotubes are single-wall nanotubes. In some embodiments, the infused carbon nanotubes are multi-wall nanotubes. In some embodiments, the infused carbon nanotubes are a combination of single-wall and multi-wall nanotubes. There are some differences in the characteristic properties of single-wall and multi-wall nanotubes that, for some end uses of the fiber, dictate the synthesis of one or the other type of nanotube. For example, single-walled nanotubes can be semi-conducting or metallic, while multi-walled nanotubes are metallic. This prophetic example shows how an E-Glass fabric material can be “infused” with CNTs using a close proximity catalysis method for in situ CNT growth.

FIG. 3 depicts system 300 for producing CNT-infused fabric using close proximity catalysis in accordance with an illustrative embodiment of the present invention. CNT growth system 300 can include an enclosed growth chamber 310, inert gas containing cavity 320, first and second roughened copper plates 110, 120, two heaters 330 configured as shown, gas inlet 340, a grinding or sanding wheel and traversing element (not shown), E-Glass fabric substrate 130, and controller 350.

E-Glass fabric substrate 130 of dimensions 60″×60″ can consist of a 10000 filament E-Glass tow woven into a simple weave fabric. E-Glass fabric substrate 130 can be placed in enclosed growth chamber 310. Within enclosed growth chamber 310, E-Glass fabric substrate 130 can be placed between first and second roughened copper plates 110, 120, as shown in FIG. 3.

First and second roughened copper plates 110, 120 can consist of two copper plates which are ¼ inch thick, and whose surface, exposed to the placed E-Glass fabric substrate 130, is roughened to a roughness height rating of 125 via grinding wheel and traversing element (not shown). With E-Glass fabric substrate 130 in place, first and second roughened copper plates 110, 120 can each be brought within intimate contact with E-Glass fabric substrate 130.

Gas inlet 340 can provide inert nitrogen gas (99.999% purity) at 60 liters/minute to fill inert gas containing cavity 320 with an inert atmosphere.

Heaters 330, which can be configured as shown, can heat growth chamber 310 to a temperature of 685° C., as controlled via controller 350, which is the temperature required for close proximity catalysis and CNT growth.

When the growth temperature is achieved, gas inlet 340 can provide a mixture of 4% acetylene gas in 60 liters/minute nitrogen gas flow. These flow conditions can be applied for 10 minutes while maintaining the 685° C. growth temperature.

After growth is completed, gas inlet 340 can stop flowing acetylene gas while maintaining nitrogen flow. Heaters 330 can be turned off and temperature can be cooled to below 400° C. When the 400° C. temperature is achieved, the first and second roughened copper plates 110, 120 can be lifted away from the E-Glass fabric substrate 130. CNT growth chamber 310 can be opened and E-Glass fabric substrate 130 can be removed.

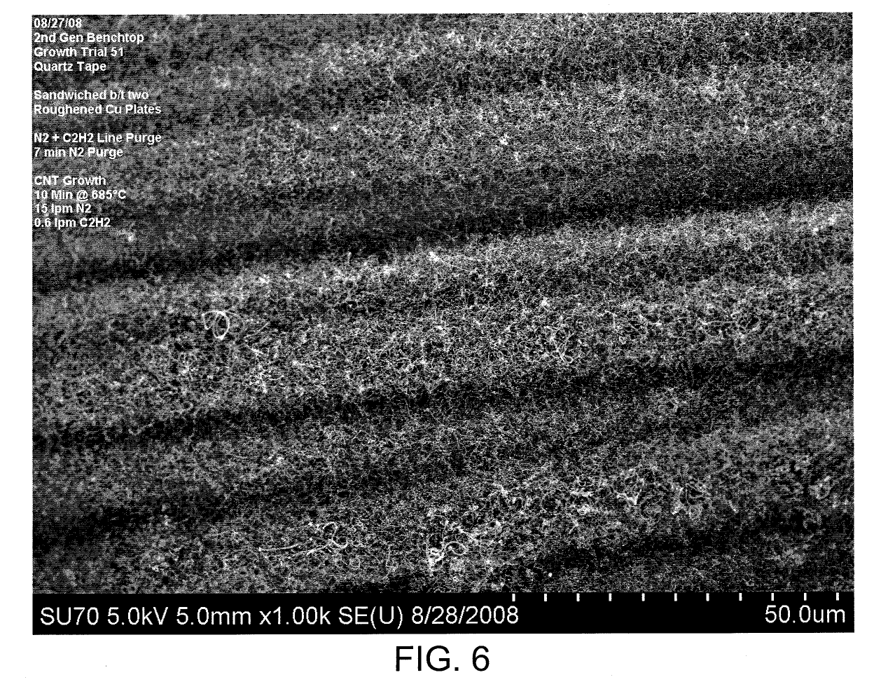

The resulting CNT infused E-Glass fabric substrate contains CNTs which can be 10-50 microns long, with diameters between 15-50 nm in diameter. The resulting CNT growth is shown in FIG. 6. Such a CNT infused E-Glass fabric material would be favorable for applications requiring improved electrical and thermal properties.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other processes, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. A method for carbon nanotube synthesis comprising:
providing in a growth chamber, a substrate in close proximity with a surface of a first plate comprising a catalyst;
heating the growth chamber to a temperature sufficient to cause transfer of catalytic particles from the first plate to the substrate; and
growing carbon nanotubes on the substrate by directing feed gas to the substrate.

2. The method of claim 1, comprising a second plate; wherein the substrate is disposed between the first plate and the second plate.

3. The method of claim 2, wherein the second plate comprises a catalyst.

4. The method of claim 1, wherein the plate is roughened prior to heating.

5. The method of claim 4, comprising roughening the plate prior to heating.

6. The method of claim 1, comprising, prior to heating, ensuring that the growth chamber comprises an inert environment.

7. The method of claim 1, wherein the catalyst comprises a transition metal.

8. The method of claim 7, wherein the metal comprises copper.

9. A system for carbon nanotube synthesis, comprising:
a growth chamber;
a heater configured to heat the growth chamber;
a first plate comprising a catalyst, wherein the first plate is configured to fit within the growth chamber, and wherein a surface of the first plate faces a substrate; and
a substrate configured to fit in close proximity with the surface of the first plate.

10. The system of claim 9, comprising a second plate, wherein the second plate is configured to fit within the growth chamber, wherein the surface of the first plate faces a surface of the second plate, and wherein the substrate is configured to fit between the first and second plates, and in close proximity with the surface of the second plate.

11. The system of claim 10, wherein the second plate comprises a catalyst.

12. The system of claim 9, wherein the growth chamber is configured to accept an inert gas.

13. The system of claim 12, comprising an inert gas source in communication with the growth chamber.

14. The system of claim 9, wherein the growth chamber is configured to accept a feed gas.

15. The system of claim 14, wherein the feed gas comprises acetylene.

16. The system of claim 9, wherein the catalyst comprises a transition metal.

17. The system of claim 9, wherein the surface the plate is roughened.

18. The system of claim 9, wherein the close proximity comprises surface engagement.

19. The system of claim 9, wherein the catalyst comprises copper.

20. The system of claim 9, wherein the catalyst is selected from the group consisting of iron, nickel, cobalt, molybdenum, and an alloy thereof.
